(19) United States
(12) Patent Application Publication
(10) Pub. No.: US 2025/0133735 A1
(43) Pub. Date: Apr. 24, 2025

(54) NONVOLATILE MEMORY WITH ISOLATION STRUCTURE AND METHOD OF FORMING THE SAME

(71) Applicant: GLOBALFOUNDRIES U.S. Inc., Malta, NY (US)

(72) Inventors: Nicki Nico MIKA, Dresden (DE); Tom Herrmann, Dresden (DE); Thomas Melde, Dresden (DE)

(21) Appl. No.: 18/489,672

(22) Filed: Oct. 18, 2023

(51) Int. Cl. H10B 41/30; H01L 21/28; H01L 29/423; H01L 29/66; H01L 29/788

(52) U.S. Cl. CPC H10B 41/30; H10D 30/0411; H10D 30/683; H10D 30/6892; H10D 64/035

(57) ABSTRACT

A non-volatile memory structure includes a semiconductor substrate and first and second memory devices on the semiconductor substrate. Each of the first and second memory devices includes a floating gate, a tunnelling insulator under the floating gate, an isolation layer over the floating gate, and at least one of a select gate and a control gate over the isolation layer. The non-volatile memory structure further includes an erase gate shared by the first and second memory devices, a source region under the erase gate, and a shallow trench isolation structure between the erase gate and the source region. The shallow trench isolation structure increases the number of write/erase cycles that can be performed by the non-volatile memory structure.

### BACKGROUND

The present disclosure relates to memory devices, and more specifically, to non-volatile memory structures with first and second memory cells separated by an isolation structure.

Non-volatile memory (NVM) structures are computer storage devices that can be erased and re-programmed. NVM structures are commonly used in mobile devices, personal computers, servers, automobiles, digital cameras, and other electronic devices. NVM structures in the form of flash memory cells resemble standard floating-gate metal-oxide semiconductor field-effect transistors (MOSFETs), except the gate includes two parts. The current flows into the source and drain regions and is controlled by the floating gate (FG) and a control gate (CG) over the FG. The FG is surrounded by a first insulator, referred to as the tunnel insulator, and a second isolating layer, called an inter-poly dielectric (IPD).

Electrons placed in the FG are trapped and isolated. The trapped electrons increase the threshold voltage of the cell such that when a higher voltage is applied to the CG to turn the switch on, the channel becomes conductive. When an intermediate voltage between the normal threshold voltage and the higher threshold voltage is applied to the CG, a value can be read from the transistor. If the channel conducts at the intermediate voltage because the FG carries an insufficient charge, a logical “1” is indicated in the FG. In contrast, if the channel does not conduct at the intermediate voltage, a logical “0” is indicated in the FG. Hence, a logical “1” or “0” is identified based on whether current flows in the transistor when the intermediate voltage is applied to the CG. An additional electrode placed above the source region can have a voltage applied thereto to remove the electrons, thus acting as an erase gate (EG). The oxide between the EG and a buried source line of an NVM structure experiences high electric fields during erase operations.

### SUMMARY

Embodiments of the present application relate to an NVM structure with an STI structure between an erase gate and a source region.

In an embodiment, a non-volatile memory (NVM) structure includes a semiconductor substrate and first and second memory devices on the semiconductor substrate, each of the first and second memory devices including: a floating gate, a tunnelling insulator under the floating gate, an isolation layer over the floating gate, and at least one of a select gate and a control gate over the isolation layer. The NVM structure further includes an erase gate shared by the first and second memory devices, a source region under the erase gate, and a shallow trench isolation structure between the erase gate and the source region.

In an embodiment, a circuit has an NVM structure with a semiconductor substrate and first and second memory devices on the semiconductor substrate, each of the first and second memory devices including: a floating gate, a tunnelling insulator under the floating gate, an isolation layer over the floating gate, and at least one of a select gate and a control gate over the isolation layer. The NVM structure further includes an erase gate shared by the first and second memory devices, a source region under the erase gate, and a shallow trench isolation structure between the erase gate and the source region.

In an embodiment, a method of forming a non-volatile memory (NVM) structure includes forming first and second memory devices on a semiconductor substrate, each of the first and second memory devices including: a floating gate, a tunnelling insulator under the floating gate, an isolation layer over the floating gate, and at least one of a select gate and a control gate over the isolation layer. The method further includes forming a shallow trench isolation structure between the first and second memory devices, forming a source region under the erase gate, and forming an erase gate shared by the first and second memory devices.

### BRIEF DESCRIPTION OF THE DRAWINGS

FIG. 1 illustrates a NVM structure according to a first embodiment.

FIGS. 2A-2G illustrate a process of forming the first embodiment of the NVM structure.

FIG. 3 illustrates a second embodiment of a NVM structure.

FIG. 4 illustrates a third embodiment of a NVM structure.

FIGS. 5A and 5B illustrate process steps of forming the third embodiment of the NVM structure.

FIG. 6 illustrates a NVM structure according to a fourth embodiment.

FIG. 7 illustrates an embodiment of an electronic device with a NVM structure.

### DETAILED DESCRIPTION

Embodiments of the present application relate to a non-volatile memory (NVM) structure, a circuit including an NVM structure, and a method of forming an NVM structure.

A detailed description of embodiments is provided below along with accompanying figures. In the figures, features of the represented structures are not necessarily drawn to scale, and may be exaggerated for visual clarity. The scope of this disclosure is limited by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

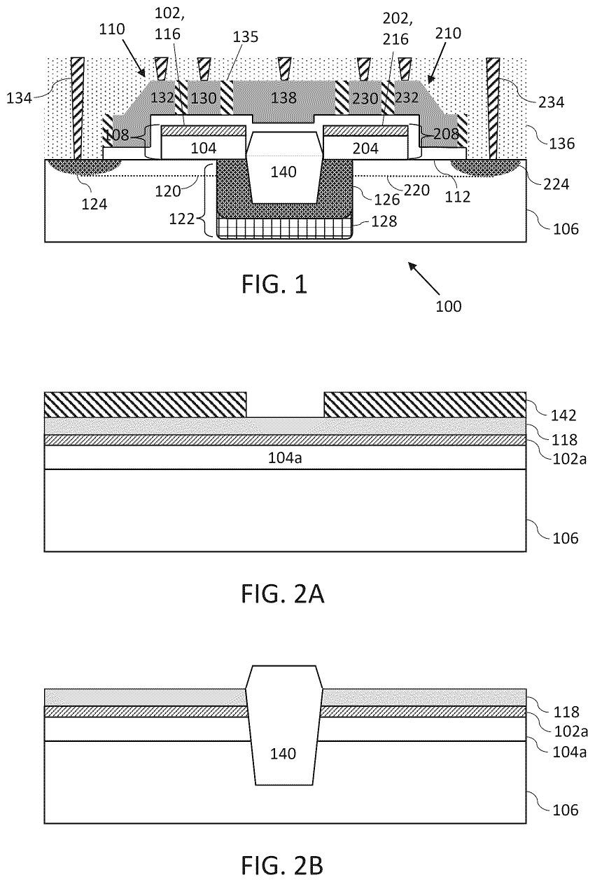

FIG. 1 shows a cross-sectional view of a first embodiment of a NVM structure 100 including two memory cells or memory devices 110 and 210. The first memory device 110 may include a stack 108 having a semiconductor layer 102 over an insulator layer 104. In one example, semiconductor layer 102 may be a semiconductor-on-insulator layer, and insulator layer 104 may be a buried insulator layer, i.e., forming semiconductor-on-insulator (SOI) layers. Collectively, semiconductor layer 102 and insulator layer 104 are patterned to form stack 108 (hereinafter “SOI stack 108”) over bulk semiconductor substrate 106. Semiconductor layer 102, insulator layer 104 and bulk semiconductor substrate 106 may be formed, for example, as any now known or later developed SOI substrate.

Semiconductor layer 102 and bulk semiconductor substrate 106 may include but are not limited to: silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). A portion of or the entire semiconductor substrate may be strained. Insulator layer 104 may include any appropriate dielectric such as but not limited to silicon dioxide. In an embodiment, insulator layer 104 is a buried oxide (BOX) layer. The precise thickness of insulator layer 104 and semiconductor layer 102 may vary with the intended application.

Memory device 110 may also include a floating gate 116 defined by semiconductor layer 102 of SOI stack 108. That is, semiconductor layer 102 provides floating gate 116 for memory device 110. Memory device 110 also includes a channel region 120 defined in bulk semiconductor substrate 106 between a source region 122 and a drain region 124. Drain region 124 is separated from source region 122 by channel region 120 in bulk semiconductor substrate 106. Source/drain regions 122, 124 may be formed using any now known or later developed techniques, and may include any appropriate dopants. Source region 122 and/or drain region 124 may extend into and out of the page for use by a number of memory devices in an array of memory devices.

In the embodiment shown in FIG. 1, source region 122 comprises a doped well 126 and a deep doped well 128. In an embodiment, the source region 122 including doped wells 126 and 128 has a width that extends from the first control gate 130 to the second control gate 230. The doped well 126 and a deep doped well 128 may be doped with the same type of dopants, e.g. N dopants or P dopants. The depth of the source region 122 is greater than the depth of drain regions 124, 224. The deep well 128 provides acceptable operating characteristics despite the presence of shallow trench isolation (STI) structure 140.

Memory device 110 also may include a control gate 130 over isolation layer 112 over SOI stack 108, an erase gate 138 over isolation layer 112 over source region 122 in bulk semiconductor substrate 106, and a bitline contact 134 coupled to drain region 124 in bulk semiconductor substrate 106. The conductor may include refractory metal liner, and a contact metal. The refractory metal liner (not labeled for clarity) may include, for example, ruthenium (Ru), tantalum (Ta), titanium (Ti), tungsten (W), iridium (Ir), rhodium (Rh) and platinum (Pt), etc., or mixtures of thereof. The contact metal may be any now known or later developed contact metal such as but not limited to copper (Cu) or tungsten (W). Similar contacts (not shown) can be formed to the various gates, described herein.

Memory device 110 also may include first control gate 130 over isolation layer 112 over first SOI stack 108, first erase gate 138 over isolation layer 112 over source region 122 in bulk semiconductor substrate 106, and first bitline contact 134 coupled to drain region 124 in bulk semiconductor substrate 106. A first select gate 132 is adjacent first SOI stack 108, allowing selection of which memory devices 110 in the array will operate collectively.

Memory device 110 includes an isolation layer 112 providing a dielectric layer or dielectric stack over SOI stack 108. Isolation layer 112 may cover sidewalls and an upper surface of SOI stack 108. Isolation layer 112 may be part of a gate dielectric layer for gates 130, 132, 138, 230 and 232. Isolation layer 112 may include any now known or later developed dielectric layer appropriate for providing an inter-poly dielectric. For example, isolation layer 112 may include: gate oxides like SiO₂, nitride SiO₂, silicon oxy-nitride (SiON), any high dielectric constant (high-K) material, and combinations thereof. In an embodiment, a portion of isolation layer 112 disposed over the SOI stacks 104 and 204 of the first and second memory devices is an oxide-nitride-oxide (ONO) layer. The ONO layer may include, for example, a silicon oxide layer over a silicon nitride layer over a silicon oxide layer, and the ONO layer may be used to control the threshold voltage of the memory devices. In another embodiment, isolation layer 112 may be a multilayer stack comprising two insulating layers and a metal layer. For example, isolation layer 112 may include a SiO₂ layer, a high-k material layer over the SiO₂ layer, and a metal layer over the high-k material layer.

Also shown in FIG. 1 is a second memory device 210. The second memory device 210 has similar components to the first memory device 110. For example, second memory device 210 includes a second floating gate 216 defined by semiconductor layer 202 of second SOI stack 208, second tunnelling insulators 214 defined by second insulator layers 204 and a second channel region 220 defined in bulk semiconductor substrate 106 between source region 122 and a second drain region 224. As with first memory device 110, second memory device 210 may include a second control gate 230 over second SOI stack 208, and a second bitline contact 234 coupled to second drain region 224 in bulk semiconductor substrate 106.

Second memory device 210 shares erase gate 138 with first memory device 110. Second memory device 210 may also include a second select gate 232 adjacent second SOI stack 208. First and second SOI stacks 108, 208 are electrically isolated from one another, e.g., by isolation layer 112 and STI structure 140. Isolation layer 112 is also over second SOI stack 208 and bulk semiconductor substrate 106 under second SOI stack 208, providing a second dielectric, and a second tunneling insulator 214 defined by second insulator layer 204 of second SOI stack 208.

The materials and structures of the elements of second memory device 210 may be substantially the same as those of the first memory device 110. The memory devices 110 and 210 may be implemented as, for example, any form of flash memory.

A shallow trench isolation structure (STI) 140 is disposed under erase gate 138 between the floating gates 116, 216 of the first and second memory structures. The isolation layer 112 is a continuous layer that extends over the STI structure 140 as well as the floating gates 116/216, and under the control, select and erase gates 130/230/132/232/138.

In the embodiment of FIG. 1, doped well 126 extends along opposite sides of STI structure 140. Accordingly, doped well 126 can form channel regions 120, 220 between source region 122 and drain regions 124 and 224 along with deep doped well 128. The portions of the source region 122 that extend along the opposite sides of the STI structure 140 may have a width of at least 10 nm, for example, to provide acceptable performance characteristics. The STI structure 140 extends below an upper surface of the substrate 106 and is at least partially surrounded by the source region 122.

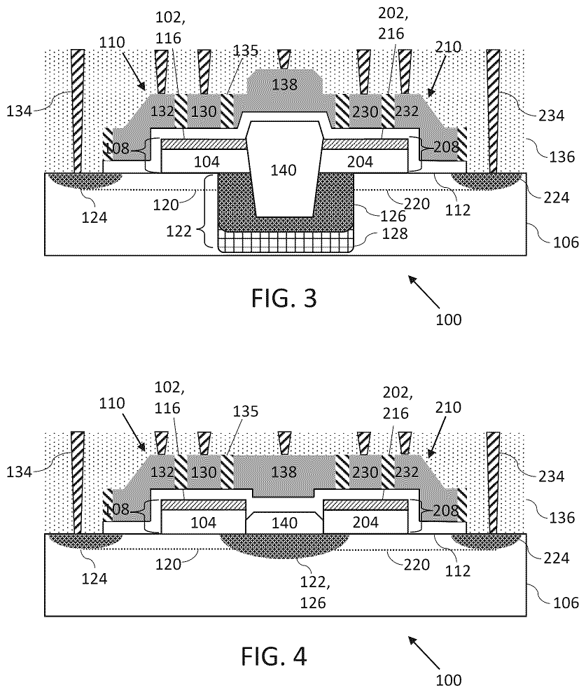

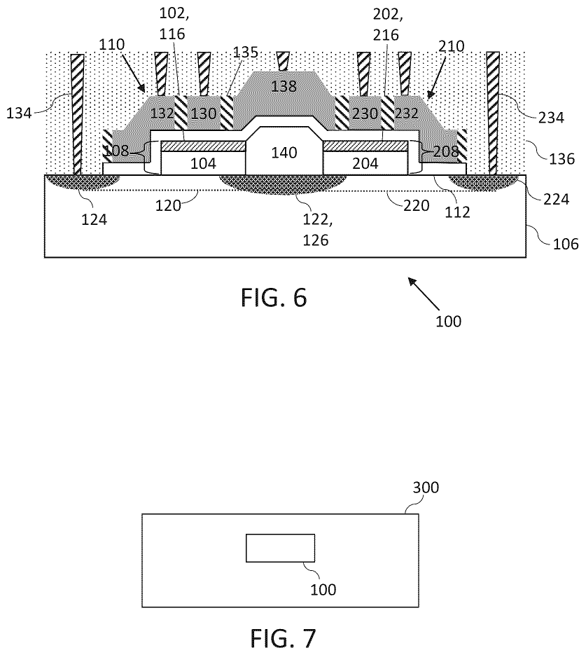

In the embodiment of FIG. 1, a portion of STI structure 140 is located below the primary surface (e.g., the surface on which insulator layers 104, 204 are located) of the substrate 106. The source region 122 covers the lower surface of STI structure 140 and the portions of STI structure 140 that are disposed below the primary surface of the substrate 106. In FIG. 1, an upper surface of the STI structure 140 is between upper and lower surfaces of the insulators 104, 204 of the first and second memory devices. In other embodiments, as seen in FIGS. 3 and 6, an upper surface of the STI structure 140 is above an upper surface of the floating gates 116 of the first and second memory devices 110, 210. In various embodiments, the STI structure 140 extends between sidewalls of floating gates 116, 216 and/or the insulators 104 and 204. In such embodiments, one or more layer, e.g. a liner layer, may be present between the STI 140 and the sidewalls of the floating gates 116, 216 and/or the insulators 104 and 204.

In operation, read and program current flows through bitline contact(s) 134, 234 below select gate(s) 132, 232 and below floating gate(s) 116, 226 into channel region(s) 120, 220, through buried source region 122, and then is collected by a sourceline contact (not shown-located into or out of page of cross-sections shown) coupled to buried source region 122. One or more select line may be coupled to select gate(s) 132, 232 for activating and deactivating memory devices 110, 210, respectively, to implement operations of NVM structure 100. Erase gate 138 is not active during read and program operations, and typically is kept at source-line voltage. Keeping all terminals at zero voltage and applying a high positive bias to the erase gate(s) 138 is one option for erase operation of the memory cells.

The STI structure 140 is located between the erase gate 138 and buried source region 122, and limits the electric field experienced by the erase gate oxide (isolation layer 112) during an erase operation, thereby extending the functional life of first and second memory devices 110 and 210. The STI structure 140 results in a substantially larger effective gate dielectric thickness for erase gate 138 compared to control and select gates 130, 230, 132, 232.

As recognized in the art, NVM structure 100 may also be part of an array of similarly structured memory devices. In this case, NVM structure 100 includes select gates 132, 232 adjacent SOI stack 108, allowing selection of which memory devices in the array will operate collectively in a known fashion. In other embodiments, the select gates 132, 232 are absent, and a single control gate 130, 230 is used to control each memory device.

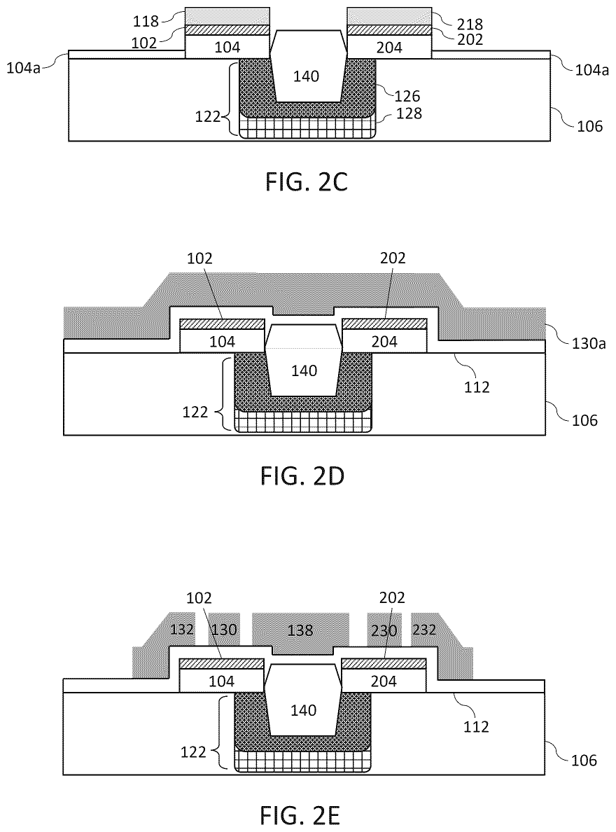

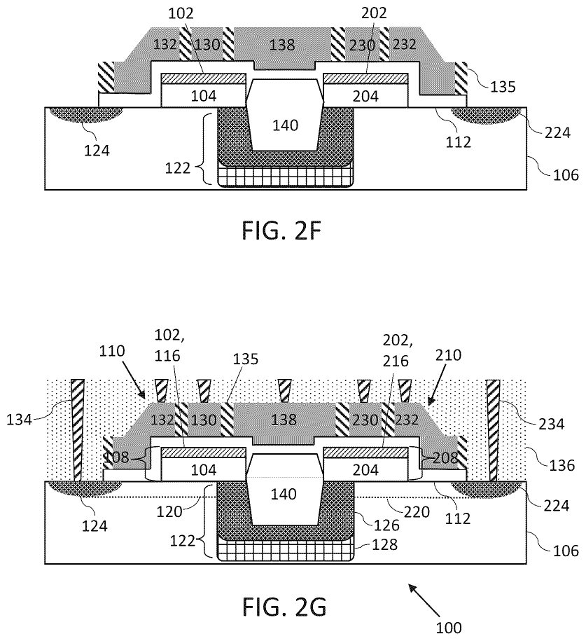

FIGS. 2A to 2H illustrate a process of forming the first embodiment of NVM structure 100 illustrated in FIG. 1. In FIG. 2A, the process includes providing a substrate 106 with an insulator layer 104a, a semiconductor layer 102a over the insulator layer 104, and a pad oxide layer 118 over the semiconductor layer 102a. A hard mask material, e.g. a nitride material, is deposited on the pad oxide layer 118 and etched to form hard mask pattern 142.

The hard mask pattern 142 is used to etch a trench that extends through the pad oxide layer 118, semiconductor layer 102a, insulator layer 104a and a portion of the substrate 106. The trench is filled with an STI material such as silicon oxide, and the hard mask pattern 142 is removed, resulting in the structure shown in FIG. 2B.

Next, an etching process is performed to remove portions of the semiconductor layer 102a, insulator layer 104a, and pad oxide layer 118, while leaving a thin layer of insulator layer 104a over edges of the portion of substrate 106 shown in FIG. 2C. The etching process may use an etch mask aligned with pad oxide layers 118 and 218 so that the etching process also removes a portion of the STI structure 140. In such an embodiment, the etching process may reduce the size of STI structure 140 so a top surface of the STI structure is below a top surface of the semiconductor layers 102 and 202. In another embodiment, the etch mask covers STI structure 140 as well, resulting in the structure shown in FIG. 3.

Two well implant processes are then performed to form doped well 126 and deep doped well 128, respectively of source region 122. It is recognized that source region 122 may extend into and out of the page for use by a number of memory devices in an array of memory devices. A pad oxide wet cleaning operation is then performed to remove remaining portions of insulator layer 104a from the substrate 106.

As seen in FIG. 2D, a dielectric material is formed over the entire structure shown in FIG. 2C to form isolation layer 112. As noted above, the dielectric material of isolation layer 112 may be any number of dielectric materials. In one embodiment, isolation layer 112 is silicon oxide. In another embodiment, isolation layer 112 may be a multilayer material comprising a lower layer of SiO₂, a middle layer of a high-k dielectric material, and a top layer of a metal material which is in contact with the gate material. The dielectric material may be formed using deposition or growth techniques as known in the art.

A gate material 130a is then formed over the isolation layer 112, resulting in the structure shown in FIG. 2D. In one example, the gate material 130a is a polysilicon that is formed with an epitaxial growth process. Although the gate material 130a is shown as a single material that will be used to form control, select and erase gates, in another embodiment, different materials may be used to form one or more of the different gates as known in the art. The structure in FIG. 2D is patterned to remove portions of gate material 130a to form gate structures 130, 132, 138, 230 and 232 as shown in FIG. 2E.

As seen in FIG. 2F, spacers 135 are formed in the spaces between adjacent gates and over outer sidewalls of select gates 132 and 232. The material of spacers 135 may be an insulating material. For example, the spacer material may be an oxide of metal or silicon, or a high temperature ceramic material such as SiBCN. In an embodiment, a layer of spacer material is deposited over the structure shown in FIG. 2E. Portions of the spacer and portions of isolation layer 112 may be removed by a dry or wet etch process to expose portions of the substrate past the edges of select gates 132 and 232 and to remove spacer material from the top surfaces of the gates.

A third implantation process is performed to form drain regions 124 and 224 for the respective memory devices 110 and 210. In another embodiment, the drain regions 124 and 224 are formed by epitaxial deposition of doped semiconductor material. The drain regions 124 and 224 may be formed using any now known or later developed techniques and may include any appropriate dopants. It is recognized that drain regions 124 and 224 may extend into and out of the page for use by a number of memory devices in an array of memory devices. An interlayer dielectric material is deposited over the entire structure to fill spaces between the gates and cover top surfaces of the gates, thereby forming interlayer dielectric 136.

Bitline contacts 134 and 234 may be formed using any now known or later developed process. In one non-limiting example, contact 134 may be formed by patterning a mask over an interlayer dielectric (ILD) 136 over memory device 110, etching a contact opening to the respective drain region 124, and forming a conductor in the openings. The conductor may include a refractory metal liner and a contact metal as described above. Additional contacts for the gates may be formed at the same time or in a different process step, resulting in the structure shown in FIG. 2G.

FIG. 3 shows a second embodiment of an NVM structure 100 in which the STI structure 140 is larger than the first embodiment shown in FIG. 1. The top surface of STI structure 140 in the embodiment of FIG. 3 is above the top surface of insulators 104 and 204 and above the top surface of floating gates 216 and 218. In another embodiment, the top surface of STI structure 140 may be above the top surface of insulators 104 and 204 and below or level with the top surface of floating gates 216 and 218. Compared to the embodiment of FIG. 1, the embodiment of FIG. 3 provides a thicker barrier between erase gate 138 and buried source region 122, resulting in further durability of the NVM structure 100. The depth and/or concentration of buried source region 122 may be increased compared to the embodiment of FIG. 1 to reduce resistance.

The second embodiment of FIG. 3 may be formed using substantially the same process described above with respect to FIGS. 2A to 2G, except that the mask used to form the structure shown in FIG. 2C may be designed to cover the STI structure 140 during the further patterning of the pad oxide layer 118, semiconductor layer 102a and insulator layer 104a.

FIG. 4 shows a third embodiment of a NVM structure 100 in which the STI structure 140 is a short shallow trench isolation structure (sSTI) located on the primary surface of semiconductor substrate 106 on the same level as insulator layers 104, 204. Unlike the first and second embodiments, the buried source region 122 is a single doped well 126 that is formed with a single doping process. No deep well is present in the third embodiment of FIG. 4. The doped well 126 may have a higher doping concentration and/or a greater depth than drain regions 124 and 224, and edges of the doped well 126 may overlap with SOI stacks 108 and 208 in the horizontal direction.

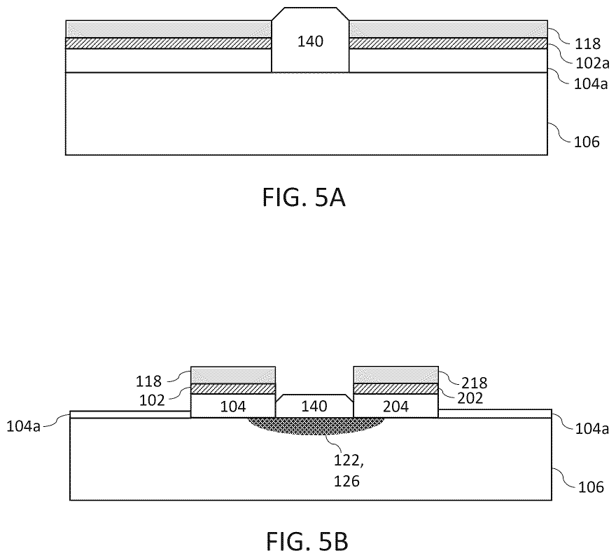

The process for forming the third embodiment is similar to the process of forming the first embodiment. Accordingly, the following description is limited to describing differences between the processes to reduce unnecessary redundancy. One difference is that during the formation of the trench shown in FIG. 2B, the pad oxide layer 118, semiconductor layer 102a and insulator layer 104a are etched using a hard mask pattern 142, while the semiconductor substrate 106 is unetched so that the bottom of the resulting trench is defined by the upper plane or primary surface of semiconductor substrate 106. An STI material is deposited in the trench and hard mask pattern 142 is removed, resulting in the structure shown in FIG. 5A.

Another difference in forming the third embodiment is the implantation step to form doped well 126. As illustrated by FIG. 5B, doped well 126 may be formed after etching the semiconductor layer 102a, pad oxide layer 118, and insulator layer 104a and the STI material to reduce the height of STI structure 140. Ions are implanted through STI structure 140 to form buried source region 122. The remaining process steps may be substantially the same as the steps described above with respect to FIGS. 2D-2G.

A fourth embodiment of a NVM structure 100 is illustrated in FIG. 6. The primary difference between the fourth embodiment of FIG. 6 and the third embodiment of FIG. 3 is the height of STI structure 140. In the fourth embodiment, the top surface of STI structure 140 is above the top surfaces of semiconductor layers 102 and 202. As a result, erase gate 138 is elevated above control and select gates 130, 132, 230 and 232. The fourth embodiment of FIG. 6 may be formed using the same processes described above with respect to the first through third embodiments, except that the mask used to etch pad oxide layer 118, semiconductor layer 102a and insulator layer 104 may be formed to cover the STI structure shown 140 in FIG. 5A.

A NVM structure 100 may be incorporated into a circuit 300 as illustrated in FIG. 7. The circuit 300 is not particularly limited, and could be any circuit that is used in a consumer or industrial appliance. For example, the circuit may be a semiconductor die with control circuitry that stores memory values in the NVM structure 100, a system-on-chip circuit, a three-dimensional integrated circuit (3DIC), a circuit board with one or more analog device, a digital semiconductor circuit, etc. Embodiments of the present disclosure expand the range of electronic devices 300 that can implement NVM structures 100 to devices for which values stored in the memory can be rewritten more times than conventional memory devices.

The NVM structure 100 as described above may be formed as separate memory chips or used as part of integrated circuit chips. In any event, the chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip may then integrated with other chips, discrete circuit elements, and/or other signal processing devices as part of either (a) an intermediate product, such as a motherboard, or (b) an end product. The end product, or electronic device 300, can be any product that includes memory chips and/or integrated circuit chips, ranging from toys and other low-end applications to advanced computer products having a display, a keyboard or other input device, and a central processor.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

1. A non-volatile memory (NVM) structure, comprising:
a semiconductor substrate;
first and second memory devices on the semiconductor substrate, each of the first and second memory devices including:
a floating gate,
a tunnelling insulator under the floating gate,
an isolation layer over the floating gate, and
at least one of a select gate and a control gate over the isolation layer,
an erase gate shared by the first and second memory devices;
a source region under the erase gate; and
a shallow trench isolation structure between the erase gate and the source region.

2. The NVM structure of claim 1, wherein the isolation layer is a continuous material layer that extends over the floating gates of the first and second memory devices and the shallow trench isolation structure.

3. The NVM structure of claim 1, wherein the first doped well extends along opposite sides of the shallow trench isolation structure.

4. The NVM structure of claim 3, wherein portions of the source region that extend along the opposite sides of the shallow trench isolation structure have a width of at least 10 nm.

5. The NVM structure of claim 1, wherein the shallow trench isolation structure extends into a trench in the substrate and is at least partially surrounded by the source region.

6. The NVM structure of claim 5, wherein the source region comprises a first doped well and a deep doped well.

7. The NVM structure of claim 5, further comprising first and second drain regions respectively coupled to the first and second memory devices, wherein a depth of the source region is greater than a depth of the first and second drain regions.

8. The NVM structure of claim 1, wherein an upper surface of the shallow trench isolation structure is above an upper surface of the floating gates of the first and second memory devices.

9. The NVM structure of claim 1, wherein an upper surface of the shallow trench isolation structure is between upper and lower surfaces of the tunnelling insulators of the first and second memory devices.

10. The NVM structure of claim 1, wherein the shallow trench isolation structure extends between sidewalls of the tunneling insulators of the first and second memory devices.

11. A circuit comprising a non-volatile memory (NVM) structure, the NVM structure comprising:
first and second memory devices on a semiconductor substrate, each of the first and second memory devices including:
a floating gate,
a tunnelling insulator under the floating gate,
an isolation layer over the floating gate, and
at least one of a select gate and a control gate over the isolation layer,
an erase gate shared by the first and second memory devices;
a source region under the erase gate; and
a shallow trench isolation structure between the erase gate and the source region.

12. The circuit of claim 11, further comprising a processor coupled to the NVM structure.

13. The circuit of claim 11, wherein the isolation layer is a continuous material layer that extends over the floating gates of the first and second memory devices and the shallow trench isolation structure.

14. The circuit of claim 11, wherein the first doped well extends along opposite sides of the shallow trench isolation structure.

15. The circuit of claim 11, wherein the shallow trench isolation structure extends into a trench in the substrate and is at least partially surrounded by the source region.

16. The circuit of claim 15, wherein the source region comprises a first doped well and a deep doped well.

17. The circuit of claim 15, further comprising first and second drain regions respectively coupled to the first and second memory devices, wherein a depth of the source region is greater than a depth of the first and second drain regions.

18. The circuit of claim 11, wherein the shallow trench isolation structure extends between sidewalls of the tunneling insulators of the first and second memory devices.

19. A method of forming a non-volatile memory (NVM) structure, the method comprising:
forming first and second memory devices on a semiconductor substrate, each of the first and second memory devices including:
a floating gate,
a tunnelling insulator under the floating gate,
an isolation layer over the floating gate, and
at least one of a select gate and a control gate over the isolation layer,
forming a shallow trench isolation structure between the first and second memory devices;
forming a source region under the erase gate; and
forming an erase gate shared by the first and second memory devices.

20. The method of claim 19, wherein the shallow trench isolation structure extends into a trench in the substrate and is at least partially surrounded by the source region, and wherein the source region comprises a first doped well and a deep doped well.
